(19) United States
(12) Patent Application Publication
(10) Pub. No.: US 2026/0255757 A1
(43) Pub. Date: Aug. 27, 2026

(54) DISPLAY DEVICE AND ELECTRONIC DEVICE INCLUDING THE SAME

(71) Applicant: Samsung Display Co., LTD., Yongin-si (KR)

(72) Inventor: Jong Hwan CHO, Yongin-si (KR)

(21) Appl. No.: 19/299,603

(22) Filed: Aug. 14, 2025

(30) Foreign Application Priority Data
Feb. 19, 2025 (KR) 10-2025-0021655

(51) Int. Cl. H10H 29/80; H10H 29/854; H10H 29/855; H10K 85/60

(52) U.S. Cl. CPC H10H 29/842; H10H 29/854; H10H 29/855; H10K 85/654

(57) ABSTRACT

A display device includes a substrate, a display layer disposed on the substrate, an encapsulation layer disposed on the display layer, a film layer disposed on the encapsulation layer, a coating layer disposed on the film layer, and a low-reflection layer disposed on the coating layer. The coating layer includes an ultraviolet absorber, and the ultraviolet absorber includes at least one of a triazine-containing compound, a benzotriazole-containing compound, and a benzophenone-containing compound.

This application is based on and claims priority to Korean Patent Application No. 10-2025-0021655, filed on Feb. 19, 2025, and all the benefits accruing therefrom under 35 U.S.C. § 119, the disclosure of which is incorporated herein by reference in its entirety.

### BACKGROUND

### 1. Field

The present disclosure relates to a display device and an electronic device including the display device.

### 2. Description of the Related Art

Display devices such as organic light emitting display devices and liquid crystal display devices include display panels manufactured by forming various layers and elements on a substrate. Recently, flexible display panels and flexible display devices including the same are being developed.

Flexible display devices may be classified as bendable display devices, foldable display devices, rollable display devices, stretchable display devices, and the like, according to their uses or forms. Among these, foldable display devices may be folded and unfolded like books.

Such flexible display devices may be equipped with flexible cover windows on display panels that display images, thereby protecting the display devices while ensuring flexibility.

### SUMMARY

Embodiments are for protecting light emitting elements from ultraviolet rays.

According to an embodiment, a display device includes a substrate, a display layer disposed on the substrate, an encapsulation layer disposed on the display layer, a film layer disposed on the encapsulation layer, a coating layer disposed on the film layer, and a low-reflection layer disposed on the coating layer, wherein the coating layer includes an ultraviolet absorber, and the ultraviolet absorber includes at least one of a triazine-containing compound, a benzotriazole-containing compound, and a benzophenone-containing compound.

The triazine-containing compound may include 2,4-bis[4-(2-ethylhexyloxy)-2-hydroxyphenyl]-6-(4-methoxyphenyl)-1,3,5-triazine.

The ultraviolet absorber may include at least one of 2,4-bis[4-(2-ethylhexyloxy)-2-hydroxyphenyl]-6-(4-methoxyphenyl)-1,3,5-triazine, 5,6-bis(4-methoxyphenyl)-1,2,4-triazin-3 (2H)-one, 2-(2-hydroxy-5-methylphenyl)benzotriazole, and 2-hydroxy-4-methoxybenzophenone.

The coating layer may include a coating agent, and the coating agent may include a random-type silsesquioxane, and the random-type silsesquioxane may include a first functional group and a second functional group, and may be represented by the following Chemical Formula 1:

(RSiO_{1.5})ₙ Chemical Formula 1
where in the Chemical Formula 1, n is 6 to 12, and R is the first functional group, the second functional group, or a combination thereof,
the first functional group includes ethylene oxide modified isocyanurate diacrylate, and the second functional group includes trimethylolpropane trimethacrylate.

In the Chemical Formula 1, n may be 8 to 10.

A mass ratio of the content of the first functional group to the second functional group may be about 3:7 to about 7:3.

A content of the coating agent in the coating layer may be about 91 weight percent (wt %) or more, and a content of the ultraviolet absorber in the coating layer may be about 2 wt % or less.

The coating layer further may include a photopolymerization initiator, and a content of the photopolymerization initiator in the coating layer may be about 2 wt % or more.

The coating layer may further include silica nanoparticles, and a content of the silica nanoparticles in the coating layer may be 3 wt % or less.

A thickness of the coating layer may be about 3 micrometers (μm) to about 7 μm.

The display device may further include a fingerprint prevention layer disposed on the low-reflection layer, where the low-reflection layer may include a plurality of high-refractive layers and a plurality of low-refractive layers, and the plurality of high-refractive layers and the plurality of low-refractive layers may be alternately stacked.

According to an embodiment, a display device includes a substrate, a display layer disposed on the substrate, an encapsulation layer disposed on the display layer, a film layer disposed on the encapsulation layer, a coating layer disposed on the film layer, and an anti-reflection layer disposed on the coating layer, wherein the anti-reflection layer includes an anti-reflection agent and an ultraviolet absorber, and the ultraviolet absorber may include at least one of a triazine-containing compound, a benzotriazole-containing compound, and a benzophenone-containing compound.

The triazine-containing compound may include 2-(4,6-diphenyl-1,3,5-triazin-2-yl)-5-hexyloxyphenol.

The anti-reflection agent may include repeatedly connected dodecafluoroheptyl acrylate (DFHA).

The benzotriazole-containing compound may include 2-(2-hydroxy-5-methylphenyl)benzotriazole, and the benzophenone-containing compound may include 2-hydroxy-4-methoxybenzophenone.

Ae mass percentage ratio of the anti-reflection agent to the ultraviolet absorber may be about 9.9:0.1 to about 9.5:0.5.

The anti-reflection layer may be about 90 nanometers (nm) to about 100 nm and may be a single layer.

According to an embodiment, an electronic device includes a memory, a processor that executes an application stored in the memory, and a display device that provides image information provided by the application, wherein the display device includes a substrate, a display layer disposed on the substrate, an encapsulation layer disposed on the display layer, a film layer disposed on the encapsulation layer, a coating layer disposed on the film layer, and a low-reflection layer disposed on the coating layer, wherein the coating layer includes an ultraviolet absorber, and the ultraviolet absorber includes at least one of a triazine-containing compound, a benzotriazole-containing compound, and a benzophenone-containing compound.

The triazine-containing compound may include 2,4-bis[4-(2-ethylhexyloxy)-2-hydroxyphenyl]-6-(4-methoxyphenyl)-1,3,5-triazine.

According to an embodiment, an electronic device includes a memory, a processor that executes an application stored in the memory, and a display device that provides image information provided by the application, where the display device includes a substrate, a display layer disposed on the substrate, an encapsulation layer disposed on the display layer, a film layer disposed on the encapsulation layer, a coating layer disposed on the film layer, and an anti-reflection layer disposed on the coating layer, where the anti-reflection layer includes an anti-reflection agent and an ultraviolet absorber, and the ultraviolet absorber includes at least one of a triazine-containing compound, a benzotriazole-containing compound, and a benzophenone-containing compound.

According to embodiments, a cover window disposed above a light emitting element includes an ultraviolet absorber to protect the light emitting element from ultraviolet rays.

### BRIEF DESCRIPTION OF THE DRAWINGS

FIG. 1 is a perspective view illustrating a display device according to an embodiment.

FIG. 2 is an exploded perspective view illustrating a display device according to an embodiment.

FIG. 3 is a perspective view illustrating a foldable display device according to an embodiment.

FIG. 4 is a block diagram illustrating an electronic device according to an embodiment.

FIG. 5 is a schematic view illustrating electronic devices according to various embodiments.

FIG. 6 is a cross-sectional view illustrating a display device according to an embodiment.

FIG. 7 is a cross-sectional view illustrating a display device according to an embodiment.

FIG. 8 is a graph showing an IR spectrum of a coating agent of a display device according to an embodiment.

FIG. 9 is a graph showing a spectral absorption spectrum of an ultraviolet absorber of a display device according to an embodiment.

FIG. 10 is a graph showing a reflection spectrum of an anti-reflection agent of a display device according to an embodiment.

FIG. 11 is a graph showing an X-ray photoelectron spectroscopy (XPS) analysis of an anti-reflection agent of a display device according to an embodiment.

FIG. 12 is a graph showing a spectral absorption spectrum of an ultraviolet absorber of a display device according to an embodiment.

FIG. 13 is a graph comparing spectral absorption spectra of ultraviolet absorbers of a display device according to an embodiment.

FIG. 14 is a view illustrating a manufacturing process of an anti-reflection layer of the display device shown in FIG. 7.

### DETAILED DESCRIPTION

Hereinafter, various embodiments of the present disclosure will be described in detail with reference to the accompanying drawings so that those skilled in the art to which the present disclosure pertains may easily carry out the embodiments. The present disclosure may be implemented in various different forms and is not limited to the embodiments described herein.

To clearly explain the present disclosure, parts irrelevant to the description have been omitted, and throughout the specification, like reference numerals will be assigned to like or similar components.

Also, the size and thickness of each component shown in the drawings are arbitrarily shown for convenience of explanation, so the present disclosure is not necessarily limited to what is shown. Thicknesses are exaggerated in the drawings to clearly express various layers and regions. And in the drawings, for convenience of explanation, the thicknesses of some layers and regions are exaggerated.

Also, in case that a part such as a layer, film, region, or plate is said to be “on” or “above” another part, this includes both the case where it is “directly on” the other part and the case where another part is present between them. Conversely, in case that a part is said to be “directly on” another part, it means that there is no other part in between. Also, being “on” or “above” a reference part means being located above or below the reference part, and does not necessarily mean being located in the direction opposite to gravity.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

“At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Also, throughout the specification, in case that a part is said to “include” a component, it means that, unless there is a specific statement to the contrary, it does not exclude other components but may include other components.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, ±5% or ±3% of the stated value.

Also, throughout the specification, “in a plan view” means in case that the target part is viewed from above, and “in a cross-sectional view” means in case that a cross-section of the target part cut vertically is viewed from the side.

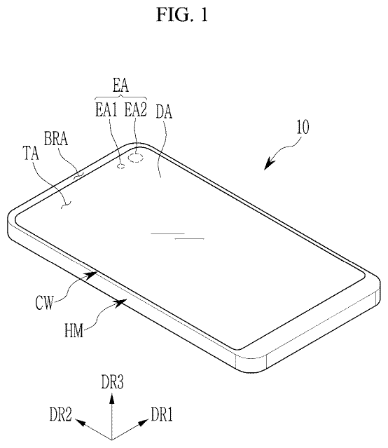

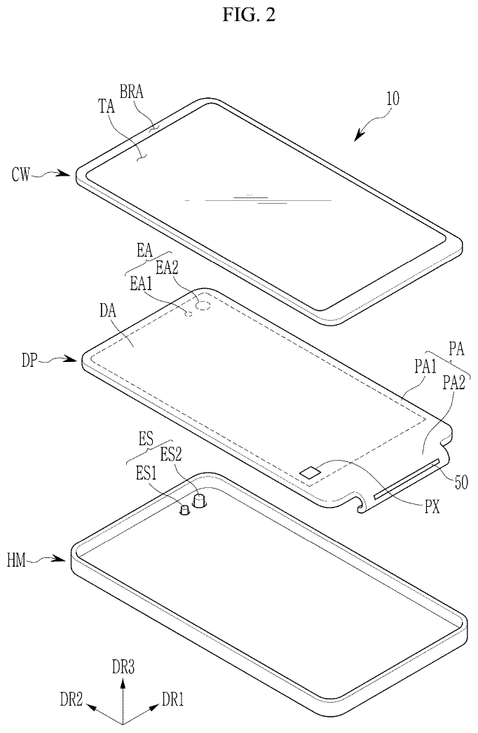

Hereinafter, a schematic structure of a display device will be examined through FIGS. 1 and 2. FIG. 1 is a perspective view illustrating a display device according to an embodiment, and FIG. 2 is an exploded perspective view illustrating a display device according to an embodiment.

Referring to FIG. 1, a display device 10 according to an embodiment is a device for displaying moving images or still images, and may be used as a display screen for various products such as portable electronic devices including mobile phones, smartphones, tablet personal computers, mobile communication terminals, as well as televisions, notebooks, monitors, advertisement boards, internet of things (IOT), or the like. Also, the display device 10 according to an embodiment may be used in wearable devices such as smart watches, watch phones, glasses-type displays, and head mounted displays (HMD). Additionally, the display device 10 according to an embodiment may be used as instrument panels in automobiles, CID (Center Information Display) arranged on the center fascia or dashboard of automobiles, room mirror displays replacing side mirrors of automobiles, and displays arranged on the back of front seats for rear seat entertainment in automobiles. FIG. 1 illustrates the display device 10 being used as a smartphone for convenience of explanation.

The display device 10 may display images toward a third direction DR3 on a display surface parallel to each of a first direction DR1 and a second direction DR2. The display surface on which images are displayed may correspond to the front surface of the display device 10 and may correspond to the front surface of the cover window CW. The images may include dynamic images as well as still images.

In this embodiment, the front surface (or upper surface) and the rear surface (or lower surface) of each member are defined based on the direction in which images are displayed. The front surface and the rear surface are opposing each other in the third direction DR3, and the normal direction of each of the front surface and the rear surface may be parallel to the third direction DR3. The separation distance between the front surface and the rear surface in the third direction DR3 may correspond to the thickness of the display panel DP in the third direction DR3.

The display device 10 according to an embodiment may detect user input applied from the outside. User input may include various forms of external inputs such as parts of the user's body, light, heat, or pressure. In an embodiment, the user's input is illustrated as the user's hand applied to the front surface. However, the present disclosure is not limited thereto. User input may be provided in various forms, and also, the display device 10 may detect user input applied to the side or rear surface of the display device 10 depending on the structure of the display device 10.

Referring to FIGS. 1 and 2, the display device 10 may include a cover window CW, a housing HM, a display panel DP, and an optical element ES. In an embodiment, the cover window CW and the housing HM may be combined to form the exterior of the display device 10.

The cover window CW may include an insulating panel. For instance, the cover window CW may comprise glass, plastic, or a combination thereof.

The front surface of the cover window CW may define the front surface of the display device 10. The transmission area TA may be an optically transparent area.

For instance, the transmission area TA may be an area having a visible light transmittance of about 90% or more.

The blocking area BRA may define the shape of the transmission area TA. The blocking area BRA may be adjacent to the transmission area TA and may surround the transmission area TA. The blocking area BRA may be an area with a relatively lower light transmittance compared to the transmission area TA.

The display panel DP may include display pixels PX that display images and a driving part 50, and the display pixels PX are located in a display area DA and a component area EA. The display panel DP may include a front surface that includes the display area DA and a non-display area PA. In an embodiment, the display area DA and the component area EA are areas where images are displayed including pixels, and at the same time, they may be areas where external input is detected as touch sensors are located above the pixels in the third direction DR3.

The transmission area TA of the cover window CW may overlap at least partially with the display area DA and the component area EA of the display panel DP. For instance, the transmission area TA may overlap with the entire front surface of the display area DA and the component area EA, or may overlap with at least a portion of the display area DA and the component area EA. Accordingly, the user may see images through the transmission area TA or provide external input based on the images. However, the present disclosure is not limited thereto. For instance, the area where images are displayed and the area where external input is detected may be separated from each other.

The non-display area PA of the display panel DP may overlap at least partially with the blocking area BRA of the cover window CW. The non-display area PA may be an area covered by the blocking area BRA. The non-display area PA is adjacent to the display area DA and may surround the display area DA. The non-display area PA does not display images, and driving circuits or driving wirings for driving the display area DA may be arranged therein. The non-display area PA may include a first non-display area PA1 located on the outside of the display area DA, and a second non-display area PA2 including a driving part 50, connection wirings, and a bending area. In the embodiment of FIG. 2, the first non-display area PA1 is located on three sides of the display area DA, and the second non-display area PA2 is located on the remaining one side of the display area DA.

A portion of the non-display area PA of the display panel DP may be bent. At this time, a portion of the non-display area PA is directed toward the rear surface of the display device 10, so that the blocking area BRA visible on the front surface of the display device 10 may be reduced, and in FIG. 2, the second non-display area PA2 may be assembled after being bent and disposed on the rear surface of the display area DA.

Additionally, the component area EA of the display panel DP may include a first component area EA1 and a second component area EA2. The first component area EA1 and the second component area EA2 may be at least partially surrounded by the display area DA. The first component area EA1 and the second component area EA2 are shown as being spaced apart from each other, but are not limited thereto and may be at least partially connected. The first component area EA1 and the second component area EA2 may be areas where optical elements (refer to ES in FIG. 2; hereinafter also referred to as components) using infrared, visible light, or sound are arranged underneath.

In the display area DA (hereinafter also referred to as the main display area) and the component area EA, a plurality of light emitting diodes and a plurality of pixel circuit units that generate and transmit light emission current to each of the plurality of light emitting diodes are formed. Here, one light emitting diode and one pixel circuit unit are called a pixel PX. In the display area DA and the component area EA, one pixel circuit unit and one light emitting diode may be formed one-to-one.

The first component area EA1 may include a display layer including a plurality of pixels and a transmission part through which light and/or sound may pass. The transmission part comprises a layer located between adjacent pixels and through which light and/or sound may pass. The transmission part may be located between adjacent pixels, and according to embodiments, a layer through which light does not pass, such as a light blocking layer, may overlap with the first component area EA1. The number of pixels per unit area (hereinafter also referred to as resolution) of pixels included in the display area DA (hereinafter also referred to as normal pixels) and the number of pixels per unit area of pixels included in the first component area EA1 (hereinafter also referred to as first component pixels) may be the same.

The second component area EA2 includes an area (hereinafter also referred to as a light transmission area) comprising a transparent layer through which light may pass, and the light transmission area does not have a conductive layer or a semiconductor layer located therein, and may have a structure that does not block light by including openings that overlap with a layer including a light blocking material, for instance, a pixel defining layer and/or a light blocking layer corresponding to the position of the second component area EA2. The number of pixels per unit area of pixels included in the second component area EA2 (hereinafter also referred to as second component pixels) may be smaller than the number of pixels per unit area of normal pixels included in the display area DA. As a result, the resolution of the second component pixels may be lower than the resolution of the normal pixels.

The second non-display area PA2 may include a bending part. The display area DA and the first non-display area PA1 may have a flat state substantially parallel to the plane defined by the first direction DR1 and the second direction DR2, and one side of the second non-display area PA2 may extend from the flat state, pass through the bending part, and then have a flat state again. As a result, at least a portion of the second non-display area PA2 may be assembled to be located on the rear side of the display area DA by being bent. In case that at least a portion of the second non-display area PA2 is assembled, it overlaps with the display area DA in a plan view, so the blocking area BRA of the display device 10 may be reduced.

The driving part 50 may be mounted on the second non-display area PA2, and may be mounted on the bending part or located on one of both sides of the bending part. The driving part 50 may be provided in the form of a chip.

The driving part 50 may be electrically connected to the display area DA and the component area EA to transmit electrical signals to the pixels of the display area DA and the component area EA. For instance, the driving part 50 may provide data signals to the pixels PX arranged in the display area DA. Or, the driving part 50 may include a touch driving circuit and may be electrically connected to touch sensors TS arranged in the display area DA and/or the component area EA. The driving part 50 may include various circuits other than the above-described circuits or may be designed to provide various electrical signals to the display area DA.

A pad unit may be located at the end of the second non-display area PA2 of the display device 10, and may be electrically connected to a flexible printed circuit board (FPCB) including a driving chip by the pad unit. Here, the driving chip located on the flexible printed circuit board may include various driving circuits or connectors for power supply to drive the display device 10. According to embodiments, a rigid printed circuit board (PCB) may be used instead of a flexible printed circuit board.

The optical element ES may be arranged under the display panel DP. The optical element ES may include a first optical element ES1 overlapping with the first component area EA1 and a second optical element ES2 overlapping with the second component area EA2. The first optical element ES1 may use infrared rays, in which case a layer through which light does not pass, such as a light blocking member, may overlap with the first component area EA1.

The first optical element ES1 may be an electronic element that uses light or sound. For instance, the first optical element ES1 may be a sensor that receives and uses light, such as an infrared sensor, a sensor that outputs and detects light or sound to measure distance or recognize fingerprints, and the like, a small lamp that outputs light, or a speaker that outputs sound. In the case of electronic elements using light, it is of course possible to use light of various wavelength bands such as visible light, infrared light, ultraviolet light, and the like.

The second optical element ES2 may be at least one of a camera, an IR camera, a dot projector, an IR illuminator, and a Time-of-Flight (ToF) sensor.

The housing HM may be combined with the cover window CW. The cover window CW may be arranged on the front surface of the housing HM. The housing HM may be combined with the cover window CW to provide an accommodation space.

The display panel DP and the optical element ES may be accommodated in the accommodation space provided between the housing HM and the cover window CW.

The housing HM may include materials with relatively high rigidity. For instance, the housing HM may include glass, plastic, or metal, or a plurality of frames and/or plates comprising a combination thereof. The housing HM may stably protect the components of the display device 10 accommodated in the internal space from external impacts.

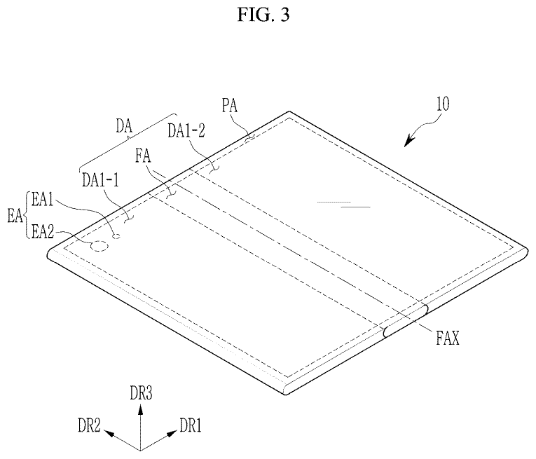

Hereinafter, the structure of a display device 10 according to another embodiment will be examined through FIG. 3. FIG. 3 is a perspective view schematically illustrating a light emitting display device according to an embodiment.

Descriptions of components identical to the aforementioned components will be omitted, and in the embodiment of FIG. 3, the display device 10 illustrates a foldable display device with a structure that folds through a folding axis FAX.

Referring to FIG. 3, in an embodiment, the display device 10 may be a foldable display device. The display device 10 may be folded inward or outward based on the folding axis FAX. In case that folded outward based on the folding axis FAX, the display surfaces of the display device 10 are each located on the outside in the third direction DR3, so that images may be displayed in both directions. In case that folded inward based on the folding axis FAX, the display surface may not be visible from the outside.

In an embodiment, the display device 10 may include a display area DA, a component area EA, and a non-display area PA. The display area DA may be divided into a first sub display area DA1-1, a second sub display area DA1-2, and a folding area FA. The first sub display area DA1-1 and the second sub display area DA1-2 may be located on the left and right sides, respectively, based on (or centered on) the folding axis FAX, and the folding area FA may be located between the first sub display area DA1-1 and the second sub display area DA1-2. At this time, in case that folded outward based on the folding axis FAX, the first sub display area DA1-1 and the second sub display area DA1-2 are located on both sides in the third direction DR3 and may display images in both directions. Also, in case that folded inward based on the folding axis FAX, the first sub display area DA1-1 and the second sub display area DA1-2 may not be visible from the outside.

The display device 10 according to embodiments may be applied to various electronic devices 1. An electronic device 1 according to an embodiment includes the above-described display device, and may further include modules or devices having other additional functions besides the display device 10.

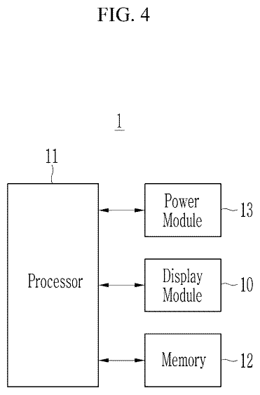

FIG. 4 is a block diagram of an electronic device according to an embodiment. An electronic device 1 according to an embodiment may include a display device (or display module) 10, a processor 11, a memory 12, and a power module 13.

The processor 11 may include at least one of a central processing unit (CPU), an application processor (AP), a graphic processing unit (GPU), a communication processor (CP), an image signal processor (ISP), and a controller.

The memory 12 may store data information desirable for the operation of the processor 11 or the display device 10. In case that the processor 11 executes an application stored in the memory 12, image data signals and/or input control signals are transmitted to the display device 10, and the display device 10 processes the provided signals to output image information through the display screen.

The power module 13 may include a power supply module, such as a power adapter or a battery device, and a power conversion module that converts power supplied by the power supply module to generate power desirable for the operation of the electronic device 1.

At least one of the components of the electronic device 1 described above may be included in the display device 10 according to the embodiments described above. Also, some of the individual modules included in one module functionally may be included in the display device, and others may be provided separately from the display device 10. For instance, the processor 11, the memory 12, and the power module 13 may be provided in the form of other devices in the electronic device 1 rather than the display device.

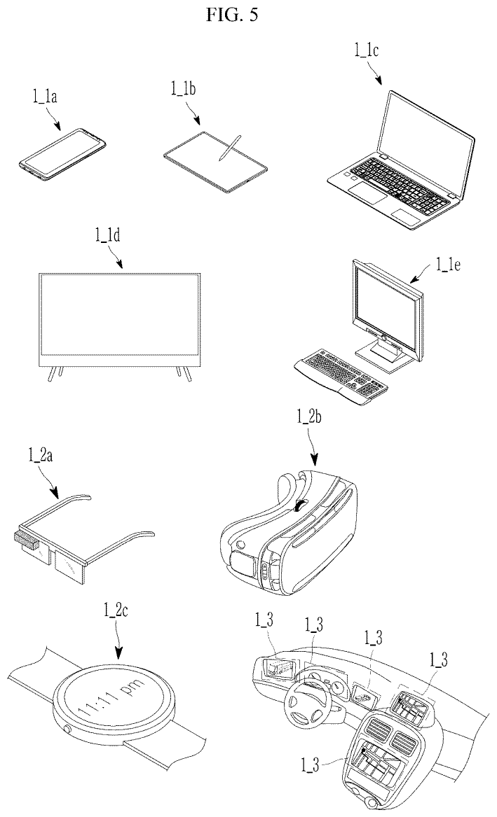

FIG. 5 is a schematic view of electronic devices according to various embodiments.

Referring to FIG. 5, various electronic devices 1 to which the display device according to embodiments is applied may include not only image display electronic devices such as smartphones 1_1a, tablet PCs 1_1b, laptops 1_1c, TVs 1_1d, desktop monitors 1_1e, and the like, but also wearable electronic devices including display devices such as smart glasses 1_2a, head mounted displays 1_2b, smart watches 1_2c, and the like, and vehicle electronic devices 1_3 including display devices such as instrument panels, center fascia, CID (Center Information Display) arranged on dashboards, room mirror displays, and the like.

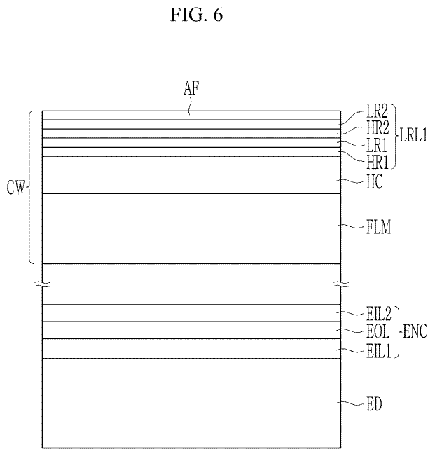

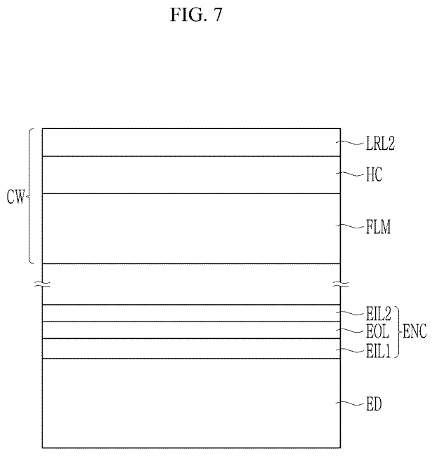

Hereinafter, the structure of the cover window of the display device will be examined with reference to FIGS. 6 and 7. FIG. 6 is a cross-sectional view schematically illustrating a portion of a display device according to an embodiment, and FIG. 7 is a cross-sectional view schematically illustrating a portion of a display device according to an embodiment.

Referring to FIG. 6, the display device according to an embodiment may include a substrate, a display layer ED disposed on the substrate, an encapsulation layer ENC disposed on the display layer ED, and a cover window CW disposed above the encapsulation layer ENC.

The substrate is a transparent substrate and may comprise a flexible material such as a polymer film.

The display layer ED may be disposed on the substrate. The display layer ED includes a device area where elements such as thin film transistors (TFTs) are formed and a light emitting area where a light emitting layer is formed. The device area and the light emitting area may be located separately or may be located to overlap with each other.

The encapsulation layer ENC may be disposed on the display layer ED. The encapsulation layer ENC may comprise an inorganic layer and an organic layer, and in an embodiment, a first inorganic layer EIL1, an organic layer EOL, and a second inorganic layer EIL2 may be sequentially disposed. The encapsulation layer ENC may include at least one inorganic layer and at least one organic layer. The encapsulation layer ENC may be integrally provided to overlap with the entire front surface of the display area, and may also be partially arranged on the non-display area. The display area may be protected from external air or moisture through the encapsulation layer ENC.

The cover window CW may be disposed above the encapsulation layer ENC.

The cover window CW may include a film layer FLM, a coating layer HC disposed on the film layer FLM, a low-reflection layer LRL1 disposed on the coating layer HC, and a fingerprint prevention layer AF. However, the structure of the cover window CW is not necessarily limited to this, and any one of these may be omitted or other components may be included, or a protective film may be further included on the lower surface.

The film layer FLM may include a film comprising a transparent material. The film may be made of, for instance, glass or plastic. If it includes a film made of plastic, the cover window CW may have a flexible property. The plastic applied to the film must have excellent transparency, mechanical strength, thermal stability, moisture barrier properties, isotropy, and the like. Instances of plastics applicable to this include, but are not specifically limited to, polyethylene terephthalate (PET), polyacrylate, polyethylene naphthalate (PEN), polymethyl methacrylate (PMMA), polyurethane (PU), polyimide (PI), or polycarbonate (PC), polyvinylidene chloride, polyvinylidene difluoride (PVDF), polystyrene, ethylene vinylalcohol copolymer, polyethersulphone (PES), polyetherimide (PEI), polyphenylene sulfide (PPS), polyallylate, tri-acetyl cellulose (TAC), cellulose acetate propionate (CAP), and the like. The film layer FLM may include one or more of the listed plastic materials. The film layer FLM of the display device according to an embodiment may include polyethylene terephthalate (PET).

The thickness of the film layer FLM may be 40 μm to 90 μm.

A coating layer HC is disposed on the film layer FLM. The coating layer HC may increase the hardness of the cover window CW by being disposed on the film layer FLM. The coating layer HC may include an ultraviolet absorber and a coating agent.

The coating layer HC of the display device according to an embodiment may include a coating agent to increase the hardness of the coating layer HC. The content of the coating agent in the coating layer HC may be 91 wt % or more. With a coating agent content of 91 wt % or more in the coating layer, the hardness, flexibility, and heat resistance of the coating layer may be maintained at a high level, and the chemical resistance, wear resistance, and friction characteristics may be excellent.

The coating agent may include a random-type silsesquioxane. The silsesquioxane may include a first functional group and a second functional group, and may be represented by the following Chemical Formula 1:

### Chemical Formula 1

(RSiO_{1.5})ₙ where in Chemical Formula 1, n may be 6 to 12, and specifically, may be 8 to 10. R may be a first functional group (R1), a second functional group (R2), or a combination thereof. The first functional group (R1) may include ethylene oxide modified isocyanurate diacrylate. The second functional group (R2) may include trimethylolpropane trimethacrylate. The second functional group (R2) may serve to increase the flexibility of the coating layer.

The random-type silsesquioxane may be represented by the following Molecular Structure Formula 1:

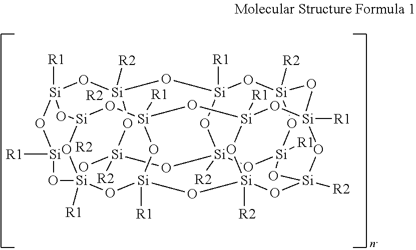

The first functional group (R1) may include ethylene oxide modified isocyanurate diacrylate (EO-modified isocyanurate Diacrylate), and may be represented by the following Molecular Structure Formula 2. EO means ethylene oxide. The first functional group (R1) may improve the heat resistance of the coating layer HC, and may serve to increase the hardness of the coating layer HC.

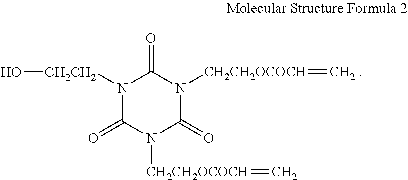

The second functional group (R2) may include trimethylolpropane trimethacrylate, and may be represented by the following Molecular Structure Formula 3. The second functional group (R2) may serve to increase the flexibility of the coating layer.

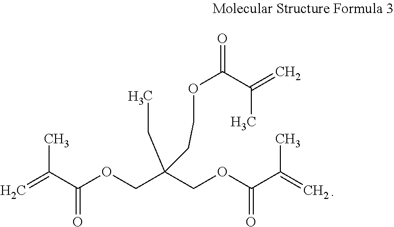

The random-type silsesquioxane may react with photopolymerization groups and crosslink between molecules, resulting in a nano-hybrid structure in which organic regions and inorganic regions are combined. Because of this structure, the coating layer may have high hardness, high flexibility and high heat resistance, and excellent chemical resistance and wear resistance.

The mass ratio of the first functional group to the second functional group (mass of the first functional group to mass of the second functional group) may be 3:7 to 7:3, and for instance, the mass ratio of the first functional group to the second functional group may be about 5:5.

The coating layer of the display device according to an embodiment includes an ultraviolet absorber. The coating layer may include an ultraviolet absorber to block ultraviolet rays with wavelengths of 280 nm to 400 nm. The content of the ultraviolet absorber in the coating layer may be 2 wt % or less.

The ultraviolet absorber may include at least one of a triazine-containing compound, a benzotriazole-containing compound, and a benzophenone-containing compound. The maximum absorption wavelength ranges may be adjusted according to the type of ultraviolet absorber used and its mass ratio.

The triazine-containing compound may include 2,4-bis[4-(2-ethylhexyloxy)-2-hydroxyphenyl]-6-(4-methoxyphenyl)-1,3,5-triazine.

2,4-bis[4-(2-ethylhexyloxy)-2-hydroxyphenyl]-6-(4-methoxyphenyl)-1,3,5-triazine and bis-ethylhexyloxyphenol methoxyphenyl triazine may be the same compound named using different nomenclatures.

2,4-bis[4-(2-ethylhexyloxy)-2-hydroxyphenyl]-6-(4-methoxyphenyl)-1,3,5-triazine may be represented by the following Molecular Structure Formula 4.

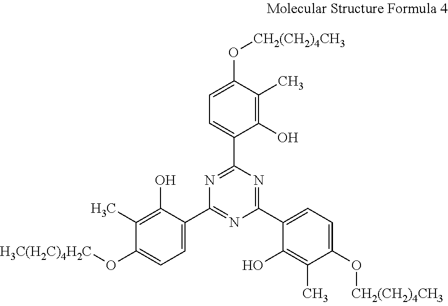

2,4-bis[4-(2-ethylhexyloxy)-2-hydroxyphenyl]-6-(4-methoxyphenyl)-1,3,5-triazine may have very high ultraviolet absorption capability in the maximum absorption wavelengths of 310 nm and 343 nm. Also, because of its excellent heat resistance, it hardly discolors and has excellent compatibility with resins such as coating agents. It also has excellent vaporization properties, enabling the formation of a uniform film through vaporization and providing a uniform ultraviolet blocking effect.

Another triazine-containing compound may include 5,6-bis(4-methoxyphenyl)-1,2,4-triazin-3 (2H)-one. The molecular structure formula may be as follows.

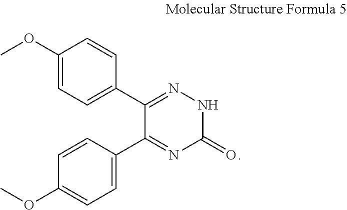 [SMILES: COc1ccc(-c2n[nH]c(=O)nc2-c2ccc(OC)cc2)cc1]

5,6-bis(4-methoxyphenyl)-1,2,4-triazin-3 (2H)-one is a triazine-containing compound that may have excellent ultraviolet absorption capacity in the ultraviolet A (UVA) and ultraviolet B (UVB) ranges.

The benzotriazole-containing compound may include, for instance, 2-(2-hydroxy-5-methylphenyl)benzotriazole. The molecular structure formula may be as follows.

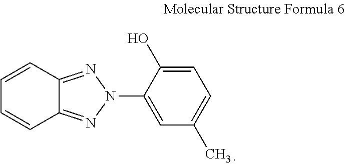 [SMILES: Cc1ccc(O)c(-n2nc3ccccc3n2)c1]

2-(2-hydroxy-5-methylphenyl)benzotriazole is a benzotriazole-containing compound that may be given various functional substituents to enhance ultraviolet blocking ability or adjust characteristics such as thermal stability.

The benzophenone-containing compound may include, for instance, 2-hydroxy-4-methoxybenzophenone. The molecular structure formula may be as follows.

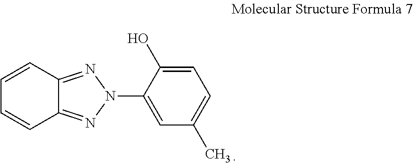 [SMILES: Cc1ccc(O)c(-n2nc3ccccc3n2)c1]

2-hydroxy-4-methoxybenzophenone is a benzophenone-containing compound that may have good compatibility with plastics.

The product of the film thickness (μm) of the coating layer HC and the concentration (wt %) of the ultraviolet absorber may be 20 to 300. If the product of the film thickness (μm) of the coating layer HC and the concentration (wt %) of the ultraviolet absorber is less than 20, there may be concerns about degradation because of low ultraviolet absorption, and if the product exceeds 300, there may be issues with reduced transparency because of coloration, and the like.

The thickness of the coating layer HC may range from about 3 μm to about 7 μm.

The coating layer HC may further include a photopolymerization initiator. The content of the photopolymerization initiator in the coating layer may be 2 wt % or more. Diphenyl(2,4,6-trimethylbenzoyl) phosphine oxide may be used as the photopolymerization initiator.

The coating layer HC may further include silica nanoparticles. The content of silica nanoparticles in the coating layer HC may be 3 wt % or less. The size of the silica nanoparticles may be 20 nm to 60 nm. The coating layer HC may achieve high hardness by further including silica nanoparticles, and the larger the content of silica nanoparticles, the better the wear resistance and friction properties may be improved.

A low-reflection layer LRL1 is disposed on the coating layer. The low-reflection layer LRL1 scatters incoming light so that the light emitted from the display layer of the display device may be clearly seen by the user. The low-reflection layer LRL1 may include a plurality of high-refractive layers HR1 and HR2 and a plurality of low-refractive layers LR1 and LR2, and the high-refractive layers HR1 and HR2 and the low-refractive layers LR1 and LR2 may be alternately stacked. The alternately stacked high-refractive layers HR1 and HR2 and low-refractive layers LR1 and LR2 may scatter incoming light from the outside to give the low-reflection layer LRL1 a low-reflection characteristic, making the light emitted by the display layer clearly visible. The alternately stacked high-refractive layers HR1 and HR2 and low-refractive layers LR1 and LR2 may be deposited by physical vapor deposition (PVD). However, the low-reflection layer LRL1 is not limited to this structure, and high-refractive materials and low-refractive materials may coexist in a single film.

A fingerprint prevention layer AF may be disposed on the low-reflection layer LRL1. The fingerprint prevention layer AF may be located at the outermost part of the cover window CW. The fingerprint prevention layer AF may include a fluorine-containing compound. The fluorine-containing compound has a small surface energy, so in case that a liquid falls on the surface of the fingerprint prevention layer, it exists in a clumped state, maintaining a spherical shape without spreading on the surface. Therefore, moisture and dust may easily slide off the surface of the fingerprint prevention layer AF.

The coating layer HC of the display device according to an embodiment may block ultraviolet A (UVA) and ultraviolet B (UVB) with wavelengths of 280 nm to 400 nm by including an ultraviolet absorber. This may improve the durability and stability of the display layer ED by inhibiting or preventing the degradation of elements included in the display layer ED because of ultraviolet rays. The coating agent of the coating layer HC may include random-type silsesquioxane to provide the coating layer HC with high hardness and high flexibility. The ultraviolet absorber may effectively block ultraviolet A (UVA) and ultraviolet B (UVB) by including a triazine-containing compound, and at the same time, it has excellent heat resistance, so there may be little discoloration even in case that absorbing ultraviolet rays. Also, an ultraviolet absorber including a triazine-containing compound may have excellent compatibility with a coating agent including silsesquioxane.

FIG. 7 is a cross-sectional view schematically illustrating a portion of a display device according to an embodiment. Descriptions overlapping with the previous descriptions will be omitted.

Referring to FIG. 7, a cover window CW according to an embodiment includes a film layer FLM, a coating layer HC disposed on the film layer FLM, and an anti-reflection layer LRL2 disposed on the coating layer HC. The structure of the cover window CW is not necessarily limited to this, and may include other components or a protective film on the lower surface.

A coating layer HC is disposed on the film layer FLM. The coating layer HC may increase the hardness of the cover window CW by being disposed on the film layer FLM. The thickness of the coating layer HC may be 3 μm to 7 μm.

An anti-reflection layer LRL2 is disposed on the coating layer HC. The anti-reflection layer LRL2 of the display device according to an embodiment includes an anti-reflection agent and an ultraviolet absorber. The anti-reflection layer LRL2, as an optical compensation layer, may not only provide an anti-reflection function but also absorb ultraviolet rays to prevent degradation of the display layer ED.

The anti-reflection agent may include dodecafluoroheptyl acrylate (DodecaFluoroHeptylAcrylate, DFHA). Specifically, it may include a compound having a structure in which dodecafluoroheptyl acrylate (DodecaFluoroHeptylAcrylate, DFHA) is repeated multiple times. For instance, dodecafluoroheptyl acrylate may be repeated 5 to 10 times, and according to embodiments, it may have a structure that is repeated 8 times. Hereinafter, dodecafluoroheptyl acrylate (DodecaFluoroHeptylAcrylate, DFHA) is referred to as DFHA. A compound having a structure in which DFHA is repeated 8 times may be represented as follows.

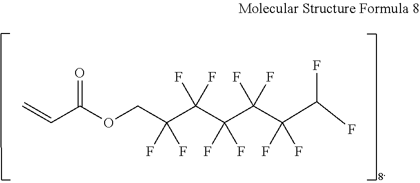

A compound having a structure in which DFHA is repeated 8 times has a refractive index of 1.342. In case that DFHA is used as an anti-reflection agent, the reflectance becomes 1.5% or less in case that the anti-reflection layer has a thickness of 100 nm, which may result in excellent anti-reflection function. Therefore, in case that such a compound is included in the anti-reflection layer, even with a single anti-reflection layer film, it is less affected by light coming from the outside, and the light emitted by the display layer may be clearly seen by the user. Moreover, the above compound is a fluorine-containing monomer with a characteristic of low surface energy, so it may simultaneously perform the role of a fingerprint prevention layer.

The ultraviolet absorber may include at least one of a triazine-containing compound, a benzotriazole-containing compound, and a benzophenone-containing compound. The maximum absorption wavelength ranges may be adjusted according to the type of ultraviolet absorber used and its mass ratio.

For instance, the triazine-containing compound may include 2-(4,6-diphenyl-1,3,5-triazin-2-yl)-5-hexyloxyphenol. The molecular structure formula may be as follows.

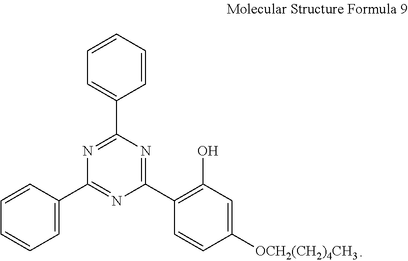

2-(4,6-diphenyl-1,3,5-triazin-2-yl)-5-hexyloxyphenol may have very high ultraviolet absorption capability in the 271 nm and 341 nm regions. It shows a very high absorption coefficient in the ultraviolet A (UVA) region below 400 nm. Therefore, 2-(4,6-diphenyl-1,3,5-triazin-2-yl)-5-hexyloxyphenol may be used at a lower concentration than other ultraviolet absorbers. Also, because this compound has excellent heat resistance, it hardly discolors and has excellent compatibility with resins such as anti-reflection agents. It also has excellent vaporization properties, enabling the formation of a uniform film through vaporization and providing a uniform ultraviolet blocking effect.

2-(4,6-diphenyl-1,3,5-triazin-2-yl)-5-hexyloxyphenol may be used at low concentrations, has a density of 1.19 grams per cubic centimeter (g/cm³) at 20° C., and is light with a vapor pressure of 9.0×10E-10 Pascal (Pa) at 25° C., making ion-accelerated vacuum deposition polymerization possible. Therefore, the ultraviolet absorber may be deposited and polymerized as a single layer on the coating layer together with the anti-reflection agent by the vacuum deposition polymerization method to be described later.

The benzotriazole-containing compound may include 2-(2-hydroxy-5-methylphenyl)benzotriazole. The molecular structure formula may be as follows.

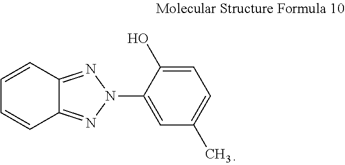 [SMILES: Cc1ccc(O)c(-n2nc3ccccc3n2)c1]

The benzophenone-containing compound may include 2-hydroxy-4-methoxybenzophenone. The molecular structure formula may be as follows.

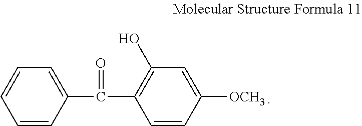 [SMILES: COc1ccc(C(=O)c2ccccc2)c(O)c1]

The mass ratio of the anti-reflection agent to the ultraviolet absorber (mass of the anti-reflection agent to mass of the ultraviolet absorber) in the anti-reflection layer LRL2 may be 9.9:0.1 to 9.5:0.5. In case that the content of the anti-reflection agent decreases, the reflectance decreases but the ultraviolet blocking effect improves. In case that the content of the anti-reflection agent increases, the reflectance increases but the ultraviolet blocking effect decreases. The reflectance and ultraviolet blocking effect may be controlled by the mass ratio in a range as described above.

The thickness of the anti-reflection layer LRL2 may be about 90 nm to about 110 nm. More specifically, the thickness of the anti-reflection layer LRL2 may be about 95 nm to about 105 nm.

The anti-reflection layer LRL2 of the display device according to an embodiment may block ultraviolet A (UVA) and ultraviolet B (UVB) with wavelengths of 400 nm or less by including an ultraviolet absorber. This may improve the durability and stability of the display layer ED by inhibiting or preventing the degradation of elements included in the display layer ED because of ultraviolet rays. Additionally, the anti-reflection agent of the anti-reflection layer LRL2 includes DFHA, so that even with just a single layer of the anti-reflection layer LRL2, the light emitted from the display layer may be clearly seen by the user.

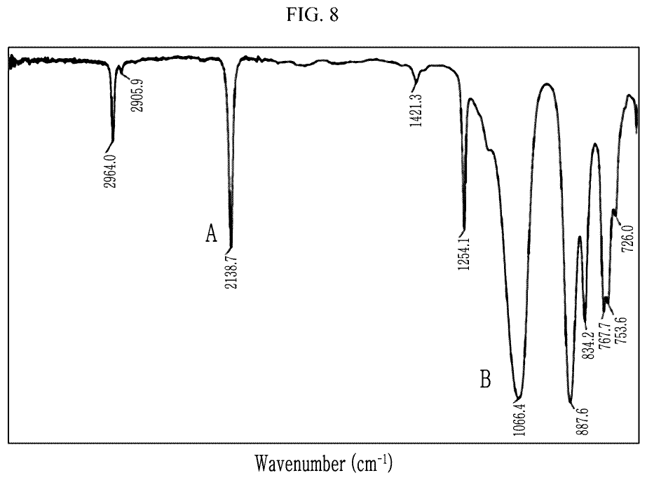

Hereinafter, compounds included in the coating agent, the ultraviolet absorber, and the anti-reflection agent will be examined with reference to FIGS. 8 to 11.

FIG. 8 is a graph showing the IR absorption spectrum of random-type silsesquioxane.

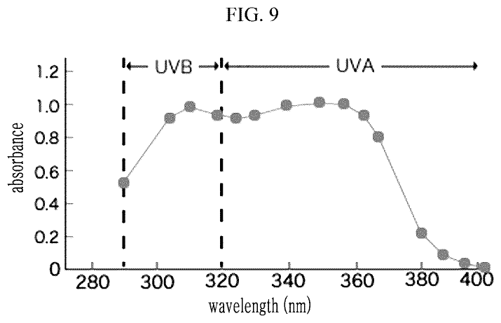

According to FIG. 8, Si—O—Si absorption is shown at 1066 cm⁻¹ (marked as B in FIG. 8), and Si—H absorption signal is shown at 2138 cm⁻¹ (marked as A in FIG. 9). These are signals that appear in silsesquioxane, so in case that the coating layer of the display device is checked with a spectral spectrum, if absorption spectra are observed at 1066 cm-1 and 2138 cm⁻¹, the coating layer may include silsesquioxane.

FIG. 9 is a graph showing the spectral absorption spectrum of 2,4-bis[4-(2-ethylhexyloxy)-2-hydroxyphenyl]-6-(4-methoxyphenyl)-1,3,5-triazine. The X-axis represents the ultraviolet wavelength (nm), and the Y-axis represents the absorbance.

According to FIG. 9, 2,4-bis[4-(2-ethylhexyloxy)-2-hydroxyphenyl]-6-(4-methoxyphenyl)-1,3,5-triazine has an absorbance close to 1 in the 310 nm and 343 nm ranges, and an absorbance of 0 or more in the 280 nm to 400 nm ranges. Therefore, in case that the coating layer of the display device according to an embodiment is checked with an IR spectrum, if it is observed to have maximum absorption wavelengths at 310 nm and 343 nm, and to absorb ultraviolet rays in the 280 nm to 400 nm ranges, the coating layer may include 2,4-bis[4-(2-ethylhexyloxy)-2-hydroxyphenyl]-6-(4-methoxyphenyl)-1,3,5-triazine.

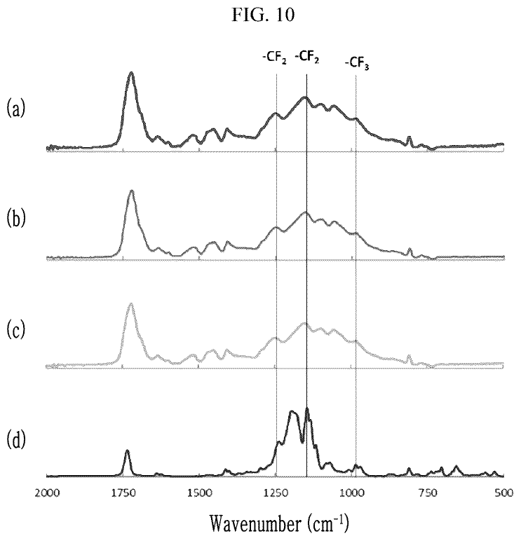

FIG. 10 is a graph showing the reflection spectrum (RAS-IR spectrum) of [DFHA]n.

[DFHA]n, n=1, i.e., DFHA monomer, is represented by the following Molecular Structure Formula 12.

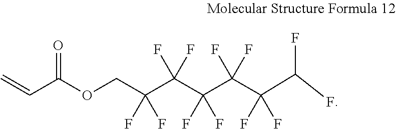 [SMILES: C=CC(=O)OCC(F)(F)C(F)(F)C(F)(F)C(F)(F)C(F)(F)C(F)F]

[DFHA]n, n=8 is a structure in which Molecular Structure Formula 12 is repeated 8 times.

FIGS. 10(a), (b), and (c) show the reflection spectra of different polymers with [DFHA]n, n=8. In all (a), (b), and (c), the presence of CF₂ and CF₃ peaks is clearly identified on the spectrum.

FIG. 10(d) shows the reflection spectrum of the monomer with [DFHA]n, n=1. In (d) as well, the presence of CF₂ and CF₃ peaks is clearly identified on the spectrum. FIG. 10(a) to (d) show that the chemical structure in DFHA was stably formed according to the infrared reflection spectrum analysis, and the characteristic peaks of CF₂ and CF₃ functional groups are clearly visible.

In case that the anti-reflection layer of the display device according to an embodiment is observed with a reflection spectrum, if a graph like FIG. 10 is observed, it may be known that it includes DFHA.

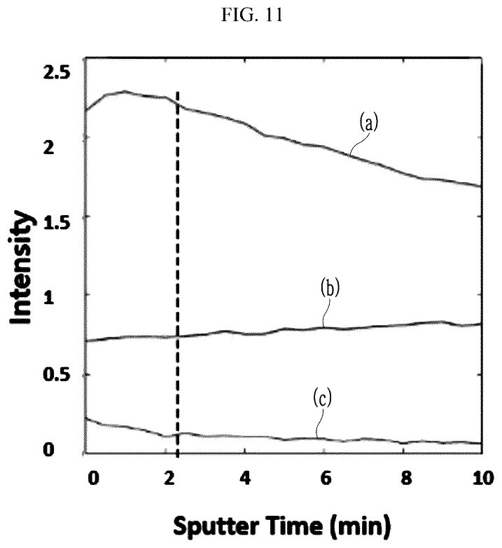

FIG. 11 is a graph showing the XPS analysis result of the anti-reflection layer including [DFHA]n, n=8. The X-axis represents the sputtering time (min), and the Y-axis represents the signal intensity.

FIG. 11 shows the elemental analysis profile according to the depth of the anti-reflection layer including [DFHA]n, n=8. At this time, the thickness of the anti-reflection layer is 100 nm. The X-axis represents the sputtering time (min), and the Y-axis represents the signal intensity. Sputtering time refers to the time to measure the component change according to the depth of the sample. The longer the time, the deeper the layer components are analyzed.

According to FIG. 11, the fluorine (F) component shows a high concentration at the surface of the anti-reflection layer. This means that the fluorine-containing groups of [DFHA]n, n=8 are abundant on the surface. As it moves away from the surface and goes inside the anti-reflection layer, the concentration of F component decreases, and instead, the concentrations of carbon (C) and oxygen (O) relatively increase.

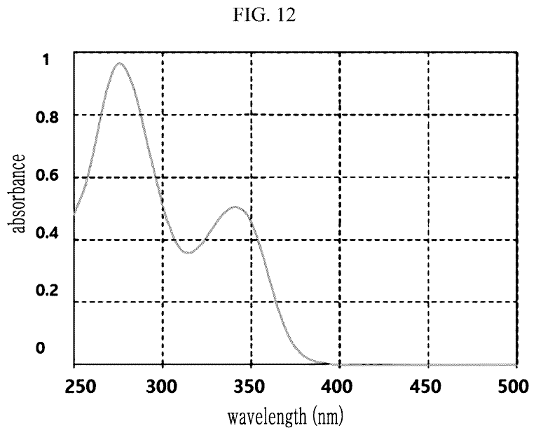

FIG. 12 is a graph showing the spectral absorption spectrum of 2-(4,6-diphenyl-1,3,5-triazin-2-yl)-5-hexyloxyphenol.

According to FIG. 12, the absorbance is 0 or more in the 250 nm to 400 nm region, and ultraviolet rays in the 271 nm and 341 nm regions are the maximum absorption wavelengths. In case that the anti-reflection layer of the display device according to an embodiment is checked with an IR spectrum, if it is observed to have maximum absorption wavelengths at 271 nm and 341 nm, and to absorb ultraviolet rays in the region below 400 nm, the anti-reflection layer may include 2-(4,6-diphenyl-1,3,5-triazin-2-yl)-5-hexyloxyphenol.

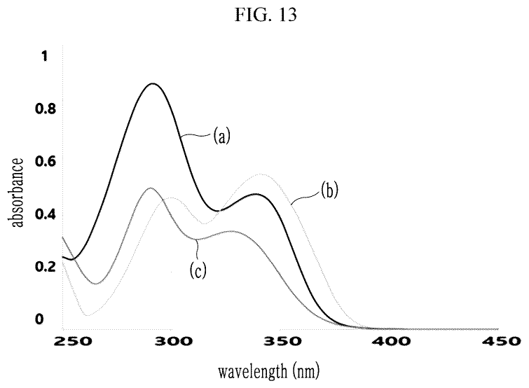

FIG. 13 is a graph showing the spectral absorption spectrum of ultraviolet absorbers.

FIG. 13 compares the ultraviolet absorption characteristics of each material. The area of the graph represents the intensity of absorbance in a specific wavelength range of each material.

FIG. 13(a) is the spectral absorption spectrum of 2-(4,6-diphenyl-1,3,5-triazin-2-yl)-5-hexyloxyphenol. Because the absorption area of FIG. 13(a) is the largest, it may be seen that the ultraviolet blocking efficiency is better than other materials.

FIG. 13(b) is the spectral absorption spectrum of 2-(2-hydroxy-5-methylphenyl)benzotriazole.

FIG. 13(c) is the spectral absorption spectrum of 2-hydroxy-4-methoxybenzophenone.

The display device according to an embodiment may include 2-(4,6-diphenyl-1,3,5-triazin-2-yl)-5-hexyloxyphenol as the ultraviolet absorber, and may further include 2-(2-hydroxy-5-methylphenyl)benzotriazole and 2-hydroxy-4-methoxybenzophenone.

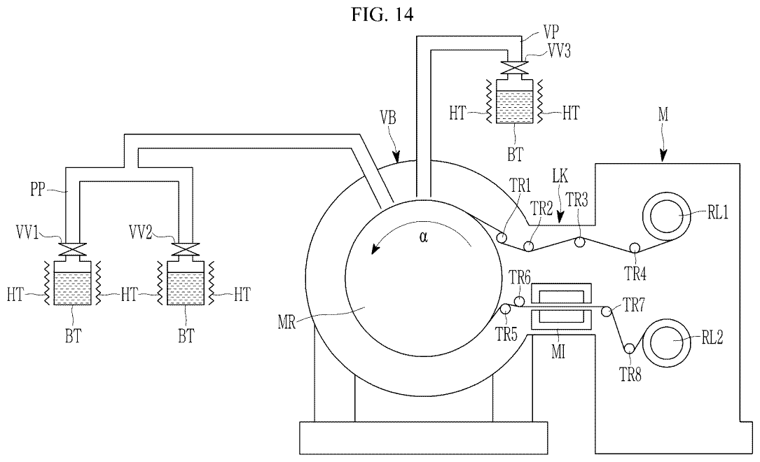

FIG. 14 is a view illustrating a manufacturing process of the anti-reflection layer of the display device shown in FIG. 7. Hereinafter, a manufacturing process of the anti-reflection layer of the display device shown in FIG. 7 will be described.

As illustrated in FIG. 14, the equipment used in the vacuum deposition process may include a vapor supply line (PP and VP) for vaporizing an anti-reflection agent and an ultraviolet absorber and supplying them into a vacuum chamber, a heater (HT) for heating and vaporizing the anti-reflection agent and the ultraviolet absorber, a boat (BT) in which the materials are contained, a connector (LK) for connecting the vapor supply line to a main roller (MR), a main body (M) accommodating a first roll (RL1) and a second roll (RL2), and the second roll (RL2) for winding the film after the deposition is completed.

In the manufacturing process of the display device according to an embodiment, in case that a film with a hard coating layer laminated on a first roll RL1 is input through a roll-on-roll process, tension first roller TR1, tension second roller TR2, tension third roller TR3, and tension fourth roller TR4 ensure that the film is input to the main roller MR while being uniformly spread. The film rotates at a constant angular velocity a on the main roller MR.

In case that the film is input while rotating, the first valve VV1, the second valve VV2, and the third valve VV3 are opened to supply the heated anti-reflection agent and ultraviolet absorber in vapor form into the vacuum chamber VB.

A microwave irradiation device MI is located at the end of the rotation part of the main roller MR. The film is input into the microwave irradiation device MI along the tension fifth roller TR5 and the tension sixth roller TR6. The microwave irradiation device MI generates plasma under conditions of ion acceleration voltage of 100 V to 500 V and substrate temperature of −30° C. to −10° C., specifically under ion acceleration voltage of 200 V and substrate temperature of −20° C., to sputter onto the film. The anti-reflection agent and the ultraviolet absorber are film-formed to have a film thickness of 100 nm on the coating layer. After film formation, the film is discharged to the main body MB along the tension seventh roller TR7 and the tension eighth roller TR8.

By the manufacturing process of the display device according to an embodiment, a single film of the anti-reflection layer LRL2 having both an anti-reflection function with a reflectance of 1.5% or less and an ultraviolet blocking function in the wavelength of 400 nm or less may be formed by simultaneously depositing and polymerizing a compound having a structure in which DFHA is repeated 8 times and a triazine-containing ultraviolet absorber at a ratio of 9.8:0.2.

While embodiments of the present disclosure have been described in detail above, the scope of rights of the present disclosure is not limited thereto, and various modifications and improvements by those skilled in the art using the basic concepts of the present disclosure defined in the following claims also fall in the scope of rights of the present disclosure.

### DESCRIPTION OF SYMBOLS

1: electronic device
10: display device
11: processor
12: memory
13: power module
CW: cover window
ED: display layer
ENC: encapsulation layer
FLM: film layer
HC: coating layer
LRL1: low-reflection layer
LR1, LR2: low-refractive layers
HR1, HR2: high-refractive layers
AF: fingerprint prevention layer
LRL2: anti-reflection layer

What is claimed is:

1. A display device comprising:
a substrate;
a display layer disposed on the substrate;
an encapsulation layer disposed on the display layer;
a film layer disposed on the encapsulation layer;
a coating layer disposed on the film layer; and
a low-reflection layer disposed on the coating layer,
wherein the coating layer includes an ultraviolet absorber, and
the ultraviolet absorber includes at least one of a triazine-containing compound, a benzotriazole-containing compound, and a benzophenone-containing compound.

2. The display device of claim 1, wherein
the triazine-containing compound includes 2,4-bis[4-(2-ethylhexyloxy)-2-hydroxyphenyl]-6-(4-methoxyphenyl)-1,3,5-triazine.

3. The display device of claim 1, wherein
the ultraviolet absorber includes at least one of 2,4-bis[4-(2-ethylhexyloxy)-2-hydroxyphenyl]-6-(4-methoxyphenyl)-1,3,5-triazine, 5,6-bis(4-methoxyphenyl)-1,2,4-triazin-3 (2H)-one, 2-(2-hydroxy-5-methylphenyl)benzotriazole, and 2-hydroxy-4-methoxybenzophenone.

4. The display device of claim 1, wherein
the coating layer includes a coating agent,
the coating agent includes a random-type silsesquioxane,
the random-type silsesquioxane includes a first functional group and a second functional group, and is represented by the following Chemical Formula 1:
(RSiO_{1.5})ₙ Chemical Formula 1
wherein in Chemical Formula 1, n is 6 to 12, and R is the first functional group, the second functional group, or a combination thereof,
the first functional group includes ethylene oxide modified isocyanurate diacrylate, and the second functional group includes trimethylolpropane trimethacrylate.

5. The display device of claim 4, wherein
in the Chemical Formula 1, n is 8 to 10.

6. The display device of claim 4, wherein
a mass ratio of the content of the first functional group to the second functional group is about 3:7 to about 7:3.

7. The display device of claim 4, wherein
a content of the coating agent in the coating layer is about 91 weight percent or more, and a content of the ultraviolet absorber in the coating layer is about 2 weight percent or less.

8. The display device of claim 7, wherein
the coating layer further includes a photopolymerization initiator, and a content of the photopolymerization initiator in the coating layer is about 2 weight percent or more.

9. The display device of claim 8, wherein
the coating layer further includes silica nanoparticles, and a content of the silica nanoparticles in the coating layer is about 3 weight percent or less.

10. The display device of claim 1, wherein
a thickness of the coating layer is about 3 micrometers to about 7 micrometers.

11. The display device of claim 1, further comprising:
a fingerprint prevention layer disposed on the low-reflection layer,
wherein
the low-reflection layer includes a plurality of high-refractive layers and a plurality of low-refractive layers, and the plurality of high-refractive layers and the plurality of low-refractive layers are alternately stacked.

12. A display device comprising:
a substrate;
a display layer disposed on the substrate;
an encapsulation layer disposed on the display layer;
a film layer disposed on the encapsulation layer;
a coating layer disposed on the film layer; and
an anti-reflection layer disposed on the coating layer,
wherein the anti-reflection layer includes an anti-reflection agent and an ultraviolet absorber, and
the ultraviolet absorber includes at least one of a triazine-containing compound, a benzotriazole-containing compound, and a benzophenone-containing compound.

13. The display device of claim 12, wherein
the triazine-containing compound includes 2-(4,6-diphenyl-1,3,5-triazin-2-yl)-5-hexyloxyphenol.

14. The display device of claim 12, wherein
the anti-reflection agent includes repeatedly connected dodecafluoroheptyl acrylate.

15. The display device of claim 12, wherein
the benzotriazole-containing compound includes 2-(2-hydroxy-5-methylphenyl)benzotriazole, and the benzophenone-containing compound includes 2-hydroxy-4-methoxybenzophenone.

16. The display device of claim 12, wherein
a mass percentage ratio of the anti-reflection agent to the ultraviolet absorber is about 9.9:0.1 to about 9.5:0.5.

17. The display device of claim 12, wherein
the anti-reflection layer is about 90 nanometers to about 100 nanometers and is a single layer.

18. An electronic device comprising:
a memory;
a processor that executes an application stored in the memory; and
a display device that provides image information provided by the application,
wherein the display device includes
a substrate;
a display layer disposed on the substrate;
an encapsulation layer disposed on the display layer;
a film layer disposed on the encapsulation layer;
a coating layer disposed on the film layer; and
a low-reflection layer disposed on the coating layer,
wherein the coating layer includes an ultraviolet absorber, and
the ultraviolet absorber includes at least one of a triazine-containing compound, a benzotriazole-containing compound, and a benzophenone-containing compound.

19. The electronic device of claim 18, wherein
the triazine-containing compound includes 2,4-bis[4-(2-ethylhexyloxy)-2-hydroxyphenyl]-6-(4-methoxyphenyl)-1,3,5-triazine.

20. An electronic device comprising:
a memory;
a processor that executes an application stored in the memory; and
a display device that provides image information provided by the application,
wherein the display device includes
a substrate;
a display layer disposed on the substrate;
an encapsulation layer disposed on the display layer;
a film layer disposed on the encapsulation layer;
a coating layer disposed on the film layer; and
an anti-reflection layer disposed on the coating layer,
wherein the anti-reflection layer includes an anti-reflection agent and an ultraviolet absorber, and
the ultraviolet absorber includes at least one of a triazine-containing compound, a benzotriazole-containing compound, and a benzophenone-containing compound.
